(19) United States
(12) Patent Application Publication
(10) Pub. No.: US 2024/0194539 A1
(43) Pub. Date: Jun. 13, 2024

(54) METHOD FOR MANUFACTURING A SEMICONDUCTOR DEVICE

(71) Applicant: COMMISSARIAT À L’ENERGIE ATOMIQUE ET AUX ENERGIES ALTERNATIVES, PARIS (FR)

(72) Inventors: Pablo ACOSTA ALBA, GRENOBLE CEDEX 9 (FR); Shay REBOH, GRENOBLE CEDEX 9 (FR)

(21) Appl. No.: 18/538,339

(22) Filed: Dec. 13, 2023

(30) Foreign Application Priority Data
Dec. 13, 2022 (FR) 2213224

(51) Int. Cl. H01L 21/8238; H01L 21/324; H01L 21/762

(52) U.S. Cl. CPC H01L 21/823878; H01L 21/324; H01L 21/76224

(57) ABSTRACT

A method for manufacturing a semiconductor device including a first semiconductor zone optimised for electron conduction and a second semiconductor zone optimised for hole conduction, the method including providing a multilayer structure including a substrate and a silicon-germanium layer disposed on the substrate; defining in the multilayer structure a first region for containing the first semiconductor zone and a second region for containing the second semiconductor zone, and subjecting the multilayer structure to laser annealing so as to modify a portion of the multilayer structure located in the second region, the portion including prior to laser annealing a part of the silicon-germanium layer, the portion having after laser annealing a germanium concentration gradient with a germanium concentration which increases towards an upper face of the portion.

### CROSS-REFERENCE TO RELATED APPLICATIONS

This application claims priority to French Patent Application No. 2213224, filed Dec. 13, 2022, the entire content of which is incorporated herein by reference in its entirety.

### FIELD

The present invention relates to a method for manufacturing a semiconductor device comprising a first semiconductor zone optimised for electron conduction and a second semiconductor zone optimised for hole conduction.

The invention may facilitate co-integration, on the same semiconductor substrate, of an N-channel field effect transistor and a P-channel field effect transistor.

### BACKGROUND

An N-channel field effect transistor (FET), commonly called an nFET transistor, is a transistor whose conduction is provided by electrons. Conversely, a P-channel field effect transistor, commonly called a pFET transistor, is a transistor whose conduction is provided by holes.

In order to improve performance of field effect transistors, especially in terms of speed, it is known to form the conduction channel of nFET transistors in a first semiconductor zone from a material promoting electron conduction and the conduction channel of pFET transistors in a second semiconductor zone from a material promoting hole conduction.

More particularly, an advanced architecture in CMOS (“Complementary Metal-Oxide-Semiconductor”) technology consists of using silicon (Si) channels for NMOS-type field effect transistors and silicon-germanium (SiGe) channels for PMOS-type field effect transistors. The use of SiGe channels for PMOS transistors is known to improve mobility of charge carriers (holes) and reduce the threshold voltage of the transistors compared with silicon alone. A high germanium concentration (typically greater than 20%) is generally sought, as charge carrier mobility increases with germanium concentration. To further improve charge carrier mobility, Si channels can be tensile-stressed and SiGe channels can be compressive-stressed.

The coexistence of a SiGe-channel PMOS transistor and a Si-channel NMOS transistor on a same substrate can be made possible by transforming a portion of a silicon layer (typically the thin layer of an SOI substrate) into a silicon-germanium portion, using a technique called localised germanium condensation. This technique comprises a step of epitaxially growing a layer of SiGe on the portion of silicon layer to be transformed and a step of oxidising the SiGe layer. This oxidation step, known as “selective” with respect to silicon, has the effect of repelling germanium atoms in the underlying silicon layer while forming a layer of silicon oxide (SiO₂) on the surface. After removal of the silicon oxide layer, the channel of the PMOS transistor is formed in the SiGe transformed portion while the channel of the NMOS transistor is formed in an unmodified portion of the silicon layer.

Germanium condensation is said to be localised, as it occurs only in the regions where PMOS transistors are desired to be formed. The initial stack of layers is different between regions accommodating NMOS transistors (Si layer only) and regions accommodating PMOS transistors (Si layer+SiGe layer). However, growing SiGe on only some regions of the silicon layer can prove to be tricky.

Furthermore, document [“Investigation of recrystallization and stress relaxation in nanosecond laser annealed Si₁₋ₓGeₓ/Si epilayers”; L. Dagault et al.; Applied Surface Science, Volume 527, 2020] describes an SiGe layer formed by epitaxy on a silicon substrate and then subjected to nanosecond laser annealing (NLA). Nanosecond laser annealing results in at least partially melting the SiGe layer. A redistribution of germanium atoms is observed during recrystallisation of the SiGe layer. The germanium atoms are concentrated towards the surface of the SiGe layer, due to a segregation mechanism. The result is a germanium concentration gradient across the thickness of the SiGe layer. This technique can be used to reduce electrical resistivity of source and drain contacts in PMOS transistors (SiGe source and drain regions).

### SUMMARY

An aspect of the invention is directed to simplifying manufacture of a semiconductor device comprising a first semiconductor zone optimised for electron conduction and a second semiconductor zone optimised for hole conduction.

According to an aspect of the invention, this purpose tends to be achieved by providing a manufacturing method comprising the following steps of:
providing a multilayer structure comprising:
   a substrate; and
   a silicon-germanium layer disposed on the substrate;
defining in the multilayer structure a first region for containing the first semiconductor zone and a second region for containing the second semiconductor zone;
subjecting the multilayer structure to laser annealing so as to modify a portion of the multilayer structure located in the second region, said portion comprising prior to laser annealing a part of the silicon-germanium layer, said portion having after laser annealing a germanium concentration gradient with a germanium concentration which increases towards an upper face of said portion.

This manufacturing method makes it possible to obtain, from a same starting stack, a first semiconductor zone optimised for electron conduction and a second semiconductor zone optimised for hole conduction. The second semiconductor zone optimised for hole conduction is obtained by concentrating the germanium atoms of the silicon-germanium layer in a region of the multilayer structure. The first semiconductor zone optimised for electron conduction is formed by an unmodified portion of the multilayer structure, located in the first region. Laser annealing is further simple and quick to implement.

Beneficially, the multilayer structure further comprises a protective layer disposed on the silicon-germanium layer, said portion extends prior to laser annealing up to the protective layer, and said portion has after laser annealing a germanium concentration which increases towards an interface with the protective layer.

In an embodiment, the multilayer structure further comprises a laser reflection layer disposed on the protective layer, and configured to decrease efficiency of laser annealing, the method further comprising, prior to laser annealing, a step of removing a portion of the laser reflection layer located in the second region of the multilayer structure.

The method may further comprise, after laser annealing, a step of removing the protective layer in the second region of the multilayer structure and a step of removing the laser reflection layer and the protective layer in the first region of the multilayer structure.

The step of defining the first and second regions of the multilayer structure can be performed after the step of providing the multilayer structure and comprise the following substeps of:
etching a trench in the multilayer structure, the trench extending through the laser reflection layer, the protective layer and the silicon-germanium layer to the substrate; and
filling the trench with an electrically insulating material through at least the entire thickness of the silicon-germanium layer.

In a first embodiment, the silicon-germanium layer has prior to laser annealing a germanium concentration of between 5% and 10%.

In a second embodiment:
the silicon-germanium layer has a germanium concentration greater than or equal to 10% prior to laser annealing;
the multilayer structure further comprises a silicon layer disposed on the silicon-germanium layer; and
said portion further comprises prior to laser annealing a part of the silicon layer.

In a third embodiment:
the silicon-germanium layer has a germanium concentration of between 5% and 10% prior to laser annealing;
the silicon-germanium layer comprises a plurality of fins distributed between the first and second regions of the multilayer structure; and
the multilayer structure further comprises electrical isolation trenches separating the fins from each other;
the multilayer structure is subjected to laser annealing so as to modify several portions of the multilayer structure located in the second region, each portion comprising at least one part of a fin prior to laser annealing.

According to a development of this third embodiment, the step of providing the multilayer structure comprises the following substeps of:
a. depositing the silicon-germanium layer onto the substrate;
b. etching the silicon-germanium layer so as to form the plurality of fins;
c. forming the electrical isolation trenches between the fins; and
d. depositing the protective layer onto the silicon-germanium layer.

In a fourth embodiment:
the silicon-germanium layer has, before laser annealing, a germanium concentration greater than or equal to 30%;
the silicon-germanium layer and a portion of the substrate are patterned in the form of a plurality of fins; and
the multilayer structure is subjected to laser annealing so as to modify several portions of the multilayer structure located in the second region, each portion comprising prior to laser annealing at least one part of a fin;
the method further comprises, after laser annealing, a step of etching the silicon-germanium layer in the first region of the multilayer structure, etching the silicon-germanium layer being selective with respect to the substrate.

According to a development of this fourth embodiment, the step of providing the multilayer structure comprises the following substeps of:
a. depositing the silicon-germanium layer onto the substrate;
b. etching the silicon-germanium layer and the portion of the substrate so as to form the plurality of fins;
c. forming the electrical isolation trenches between the fins; and
d. depositing the protective layer onto the first silicon-germanium layer.

The protective layer and the electrical isolation trenches are in an embodiment formed by a same electrically insulating material.

The manufacturing method according to an aspect of the invention may also have one or more of the following characteristics, considered individually or according to any technically possible combinations:
the laser annealing is performed by exposing the multilayer structure to laser radiation having a wavelength of between 200 nm and 600 nm and an energy density of between 0.1 J/cm² and 10 J/cm² for a duration of between 10 ns and 1000 ns;
the method further comprises a step of forming an N-channel field effect transistor, referred to as an nFET transistor, in the first region of the multilayer structure and a step of forming a P-channel field effect transistor, referred to as a pFET transistor, in the second region of the multilayer structure.

### BRIEF DESCRIPTION OF THE FIGURES

Other characteristics and benefits of the invention will be more apparent from the description given below, by way of indicating and in no way limiting purposes, with reference to the following figures.

FIGS. 1A to 1D represent a first embodiment of the manufacturing method according to the invention;

FIGS. 2A to 2D represent a second embodiment of the manufacturing method according to the invention;

FIGS. 3A to 3D represent a third embodiment of the manufacturing method according to the invention;

FIGS. 4A to 4E represent a fourth embodiment of the manufacturing method according to the invention;

FIGS. 5A to 5D represent a fifth embodiment of the manufacturing method according to the invention;

FIGS. 6A to 6D represent a sixth embodiment of the manufacturing method according to the invention;

FIGS. 7A to 7C represent a seventh embodiment of the manufacturing method according to the invention; and

FIG. 8 represents additional steps of the manufacturing method according to the invention.

For the sake of clarity, identical or similar elements are marked by identical reference signs throughout the figures.

### DETAILED DESCRIPTION

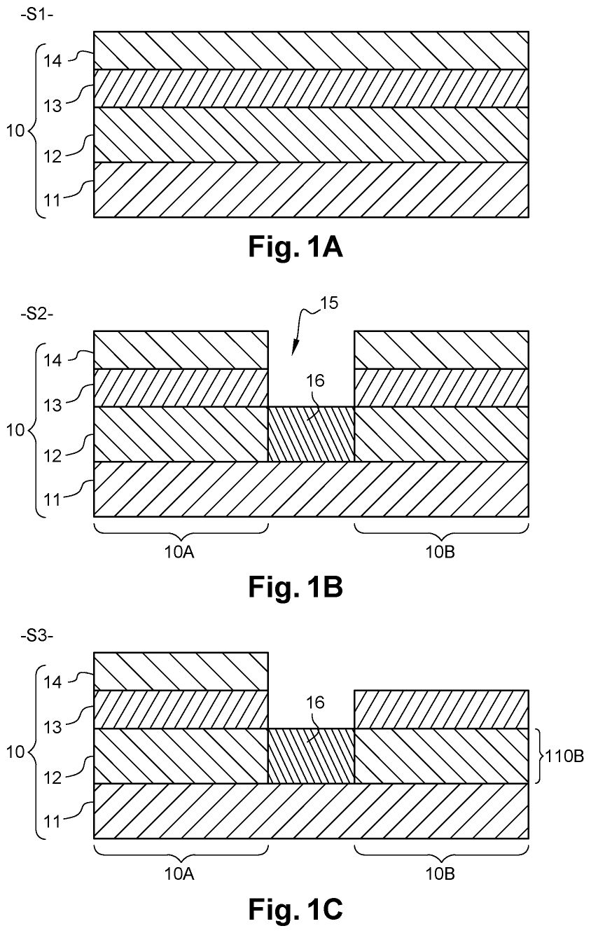

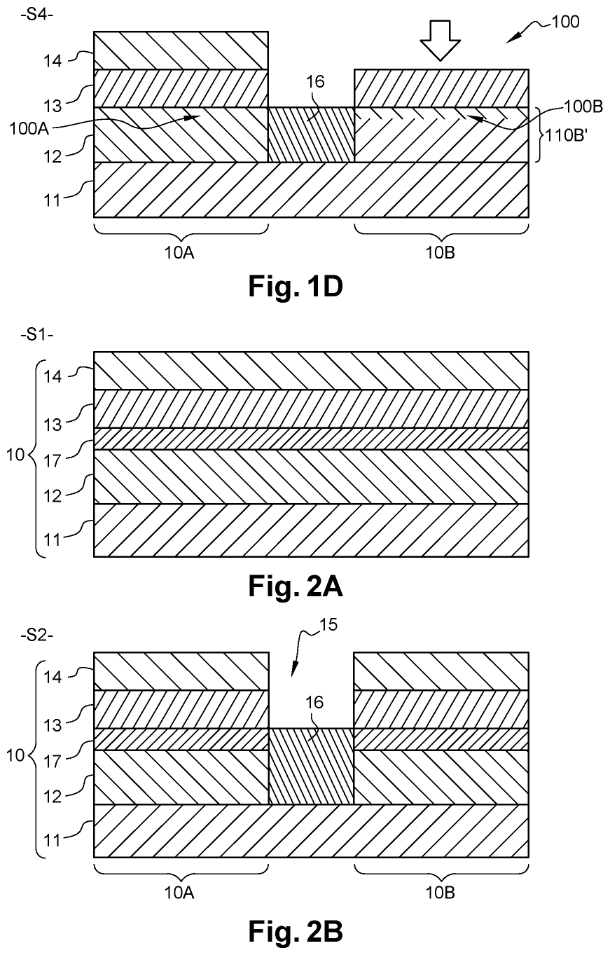

FIGS. 1A-1D, 2A-2D, 3A-3D and 4A-4E represent four embodiments of a method for manufacturing a semiconductor device comprising a first semiconductor zone 100A optimised for electron conduction and a second semiconductor zone 100B optimised for hole conduction.

Electrons have a higher mobility in the first semiconductor zone 100A than in the second semiconductor zone 100B, while holes have a higher mobility in the second semiconductor zone 100B than in the first semiconductor zone 100A.

The first semiconductor zone 100A is made of a material (semiconductor) promoting electron conduction. In an embodiment, the material of the first semiconductor zone 100A is silicon-based and has a silicon concentration greater than 90%. The first semiconductor zone 100A can especially be made of silicon or of a silicon-germanium alloy with a germanium concentration of less than or equal to 10%. The concentrations given in this description are atomic concentrations (also called atomic percentages).

The second semiconductor zone 100B is made of a material (semiconductor) promoting hole conduction. In an embodiment, the material of the second semiconductor zone 100B comprises germanium and has a germanium concentration greater than or equal to 20%. The second semiconductor zone 100B is for example made of a silicon-germanium alloy (having a germanium concentration greater than or equal to 20%).

Beneficially, the first semiconductor zone 100A is intended to form the conduction channel of one or more N-channel field effect transistors (nFET), while the second semiconductor zone 100B is intended to form the conduction channel of one or more P-channel field effect transistors (pFET). Thus, the first and second semiconductor zones 100A-100B may also be called channel zones (or layers), or active zones (or layers).

In a manner common to the four embodiments, the manufacturing method comprises the following steps S1, S2 and S4:
S1: providing a multilayer structure 10 (or stack) comprising a substrate 11 and a silicon-germanium (SiGe) layer 12 disposed on the substrate 11 (cf. FIGS. 1A, 2A, 3A-3B and 4A-4B);
S2: defining in the multilayer structure 10 a first region 10A for containing the first semiconductor zone 100A and a second region 10B for containing the second semiconductor zone 100B (see FIGS. 1B, 2B, 3A-3B and 4A-4B); and
S4: subjecting the multilayer structure 10 to laser annealing, in an embodiment of the nanosecond type, so as to modify one or more portions 110B of the multilayer structure 10 located in the second region 10B, each portion 110B comprising, before the laser annealing, part of the SiGe layer 12, each portion being modified so that, after laser annealing, it exhibits a germanium concentration gradient with a germanium concentration which increases towards an upper face of said portion (cf. FIGS. 1D, 2D, 3D and 4D).

In the appended figures, these steps S1, S2 and S4 are schematically represented by cross-section views.

It is reminded that the term “on” used above to specify the arrangement of the layers means “above”, and not “in contact”. Thus, the multilayer structure 10 may include, between two layers disposed on each other, one or more other layers (so that the two layers are not in contact).

Beneficially, the multilayer structure 10 further comprises a protective layer 13 disposed on the SiGe layer 12. Each portion 110B modified by the laser annealing then extends up to the protective layer 13 and has a germanium concentration which increases towards the interface with the protective layer 13.

Step S1 of providing the multilayer structure 10 may especially comprise a sub-step of depositing the SiGe layer 12 onto the substrate 11 and a sub-step of depositing the protective layer 13 onto the SiGe layer 12. In an embodiment, the SiGe layer 12 and the protective layer 13 are deposited so as to cover an entire face of the substrate 11 (so-called “full plate” deposition).

The substrate 11 can especially be a bulk substrate of a semiconductor material, for example silicon, or a substrate of the silicon-on-insulator (SOI) type.

The SiGe layer 12 is in an embodiment formed by epitaxy (this is referred to as growth).

The protective layer 13 in an embodiment consists of a silicon oxide, for example silicon dioxide (e.g. SiO₂). It can be formed by any deposition technique, for example PECVD, ALD, PEALD, or by thermal oxidation, especially at high temperature (or HTO, for “High Temperature Oxide”). This layer can also be obtained by a silicon growth and oxidation step. Its thickness is, for example, between 5 nm and 200 nm. The protective layer 13 can also be formed by a bilayer stack comprising an underlayer of SiO₂ (1-20 nm) disposed on an underlayer of SiN (10-80 nm).

The first and second regions 10A-10B of the multilayer structure 10, defined (or delimited) in step S2, are beneficially intended to receive field effect transistors of opposite types. More particularly, the first region 10A is to form an nFET transistor, while the second region 10B is to form a pFET transistor.

The laser annealing step S4 comprises two phases:
a first, so-called melting phase, during which the portion 110B of the multilayer structure 10 (comprising part of the SiGe layer 12) is molten; and
a second, so-called recrystallisation phase, during which the molten portion is recrystallised in the form of a semiconductor layer 110B′, 110B″ provided with the germanium concentration gradient.

During the first melting phase, the germanium atoms of the SiGe layer 12 are dispersed in the molten portion (this is known as “germanium redistribution”).

The germanium concentration gradient is the result of a segregation mechanism of the germanium atoms during the second recrystallisation phase. Since recrystallisation takes place from the substrate 11 towards the protective layer 13 (in other words, from bottom to top in the figures), germanium atoms are concentrated at the interface or in the immediate proximity of the interface between the protective layer 13 and the portion 110B of the multilayer structure 10 (instead of being pushed towards the substrate 11 during germanium condensation by thermal oxidation).

The semiconductor layer 110B′, 110B″, corresponding to the portion modified by laser annealing, is based on SiGe. It includes a first germanium-depleted part and a second germanium-enriched part disposed on the germanium-depleted part. “Germanium-depleted part” designates a portion whose germanium concentration is lower than the initial germanium concentration of the SiGe layer 12. Conversely, a portion whose germanium concentration is higher than the initial germanium concentration of the SiGe layer 12 is referred to as a “germanium-enriched part”. The germanium-enriched part of the semiconductor layer 110B′, 110B″, in contact with the protective layer 13, forms the second semiconductor zone 100B (optimised for hole conduction).

In an embodiment, the initial germanium concentration of the SiGe layer 12 and the thickness of the portion 110B (in particular in the SiGe layer 12) are chosen so as to achieve a maximum germanium concentration at the interface with the protective layer 13 of between 20% and 60%. The portion 110B can thus extend from the protective layer 13 to the substrate 11 (and thus comprise the SiGe layer 12 throughout its thickness).

The semiconductor layer 110B′, 110B″ is under biaxial in-plane compressive stress. This compressive stress, due to the different lattice parameters between silicon and silicon-germanium, is particularly strong in the germanium-enriched part, in other words in the upper portion of the semiconductor layer 110B′, 110B″ (in contact with the protective layer 13). The compressive stress increases mobility of the holes with respect to a relaxed (i.e. in-plane stress-free) layer of the same material.

Laser annealing is accomplished by exposing the surface of the multilayer structure 10 to radiation emitted by a laser source. At least some of the laser radiation passes through the protective layer 13 in the second region 10B of the multilayer structure 10. However, the protective layer 13 is not molten by the laser radiation.

The laser radiation beneficially has a wavelength of between 200 nm and 600 nm and an energy density of between 0.1 J/cm² and 10 J/cm². The duration of exposure to the laser radiation (for each area unit of the protective layer 13) may be between 10 ns and 1000 ns, in an embodiment between 20 ns and 300 ns.

The protective layer 13 also called a capping layer improves the surface condition of the semiconductor layer 110B′, 110B″. More particularly, the protective layer 13 prevents contamination and reduces roughness of the surface of the semiconductor layer 110B′, 110B″. This improved surface condition is particularly beneficial for the performance of the pFET transistor.

A preferred way of locating the laser annealing in the second region 10B of the multilayer structure 10 consists in using a laser reflection layer 14. This laser reflection layer 14 is configured to decrease efficiency of the laser annealing, by reflecting a large portion of the laser radiation. The laser reflection layer 14 is formed only in the first region 10A of the multilayer structure, so that the laser radiation reaching this region is reflected and does not affect the underlying layers of the multilayer structure 10.

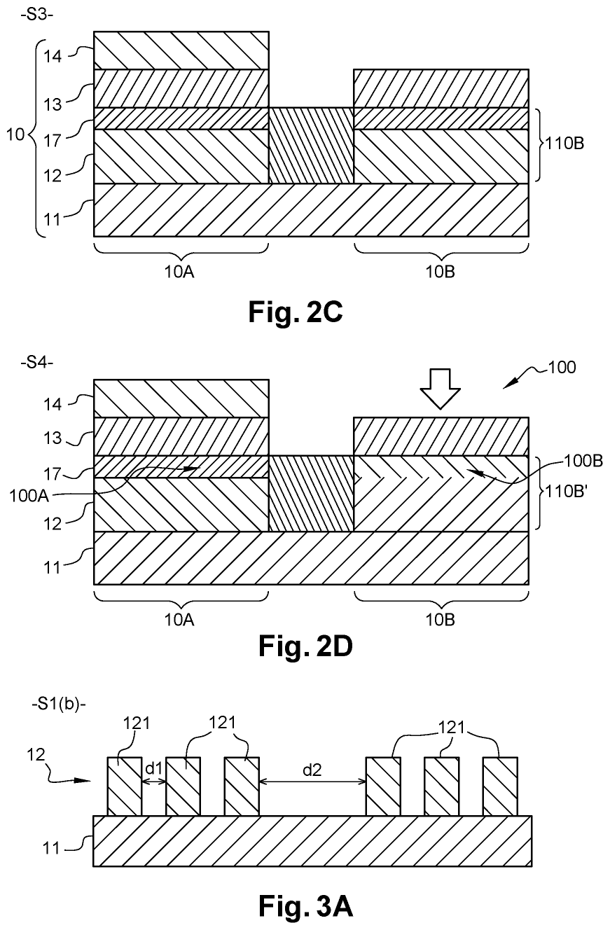

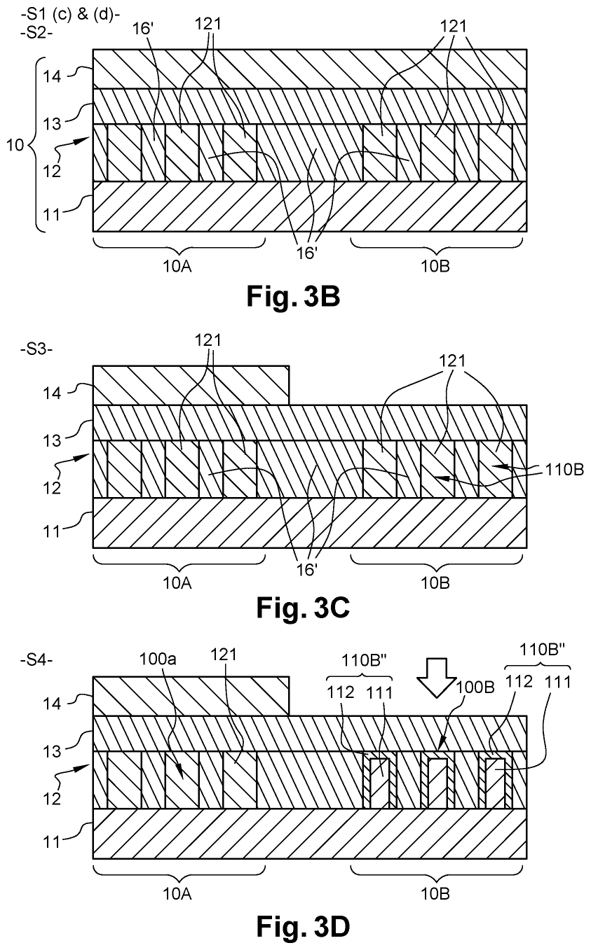

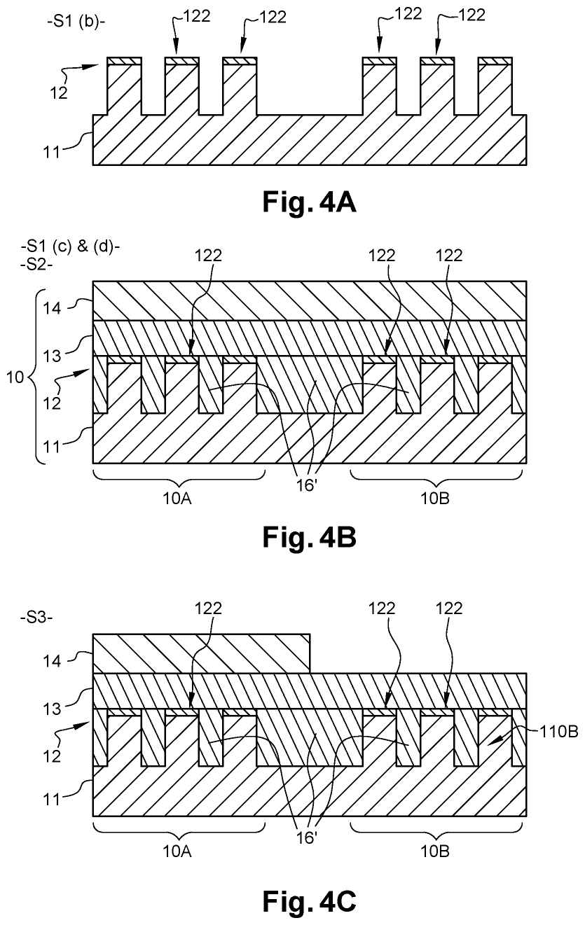

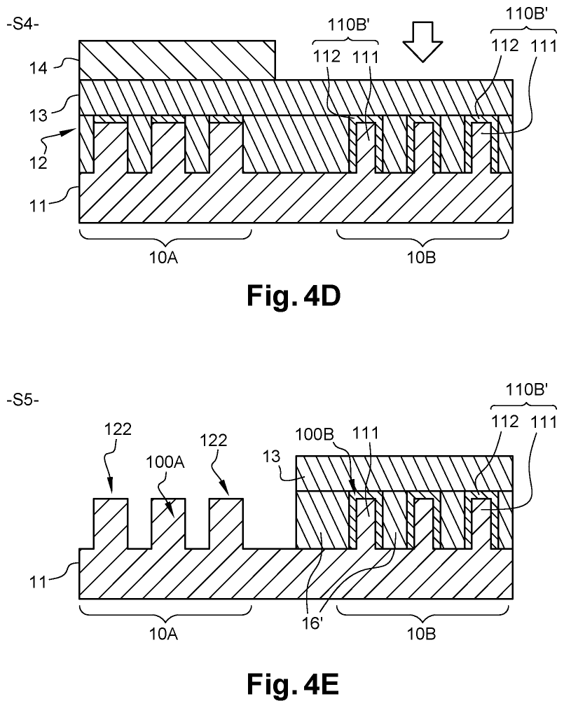

Thus, in the embodiments of FIGS. 1A-1D, 2A-2D, 3A-3D and 4A-4E, the multilayer structure 10 provided in step S1 further comprises the laser reflection layer 14 disposed on the protective layer 13 (or on the SiGe layer 12 in the absence of the protective layer 13) and the manufacturing method further comprises, before the laser annealing step S4, a step S3 of removing a portion of the laser reflection layer 14 located in the second region 10B of the multilayer structure 10 (cf. FIG. 1C, FIG. 2C, FIG. 3C and FIG. 4C).

The laser reflection layer 14 may be formed by a layer of silicon nitride (e.g. Si₃N₄) whose thickness is chosen to obtain reflective behaviour at the wavelength of the laser radiation. The thickness of the silicon nitride layer is in an embodiment between 10 nm and 60 nm. Alternatively, the laser reflection layer 14 can be formed by a stack of several sublayers, for example a first silicon dioxide (SiO₂) sublayer and a second silicon nitride (Si₃N₄) sublayer disposed on the first sublayer.

A laser reflection layer 14 can be easily limited to a region of the multilayer structure (for example by etching through a hard or resin mask) even if that region has a small surface area.

FIGS. 1A to 1D illustrate a first embodiment of the manufacturing method.

With reference to FIG. 1A, the multilayer structure 10 provided in step S1 successively comprises the substrate 11, the SiGe layer 12, the protective layer 13 and the laser reflection layer 14. The SiGe layer 12 has a germanium concentration of between 5% and 10%, for example equal to 5%. Its thickness may be between 5 nm and 100 nm.

In step S2 of FIG. 11B, the first and second regions 10A-10B of the multilayer structure 10 are defined (or delimited) by etching a trench 15 in the multilayer structure 10. The trench 15 extends through the laser reflection layer 14, the protective layer 13 and the SiGe layer 12 to the substrate 11. The laser reflection layer 14, the protective layer 13 and the SiGe layer 12 thus each comprise a first portion located in the first region 10A and a second portion located in the second region 10B. The trench 15 can also extend partly into the substrate 11 (a surface portion of the substrate 11 is thereby etched). The trench 15 is then at least partially filled with an electrically insulating material in order to form an electrical isolation trench 16 (also referred to as Shallow Trench Isolation (STI)). The electrically insulating material is deposited over at least the entire thickness of the SiGe layer 12. Thus, the electrical isolation trench 16 separates and electrically insulates both portions of the SiGe layer 12. The electrically insulating material is for example a silicon oxide (e.g. SiO₂) or a silicon nitride (e.g. Si₃N₄).

FIG. 1C represents the step S3 of removing the second portion of the laser reflection layer 14, located in the second region 10B of the multilayer structure 10. Removal can be carried out by etching the laser reflection layer 14 (for example made of Si₃N₄) through a mask, etching being beneficially selective with respect to the protective layer 13 (for example of SiO₂).

Finally, with reference to FIG. 1D, the laser annealing step S4 is carried out so as to obtain the semiconductor layer 110B′ having the germanium concentration gradient. As previously indicated, the germanium-enriched part obtained in the second region 10B (in contact with the protective layer 13) forms the second semiconductor zone 100B (optimised for hole conduction). The first semiconductor zone 100A (optimised for electron conduction) is, in this first embodiment, formed by an unmodified portion (by laser annealing) of the SiGe layer 12.

FIGS. 2A to 2D illustrate a second embodiment of the manufacturing method.

This second embodiment differs from the first embodiment mainly in the constitution of the multilayer structure 10 (also referred to as the starting stack).

With reference to FIG. 2A, the multilayer structure 10 provided in step S1 comprises, further to the substrate 11, the SiGe layer 12, the protective layer 13 and the laser reflection layer 14, a silicon layer 17 disposed between the SiGe layer 12 and the protective layer 13. The SiGe layer 12 has a germanium concentration of 10% or more. Its thickness can be between 5 nm and 100 nm. The thickness of the silicon layer 17 is in an embodiment between 5 nm and 30 nm.

The first and second regions 10A-10B of the multilayer structure 10 are defined in step S2 of FIG. 2B in substantially the same way as described in connection with FIG. 1B. As the trench 15 extends from the laser reflection layer 14 to the substrate 11, it also passes through the silicon layer 17. The electrically insulating material deposited therein to form the electrical isolation trench 16 extends at least through the entire thickness of the SiGe layer 12 and the silicon layer 17.

The portion 110B of the multilayer structure modified (molten and recrystallised) during the laser annealing step S4 comprises part of the silicon layer 17, in addition to part of the SiGe layer 12 (see FIG. 2C before annealing and FIG. 2D after annealing). The molten portions of the silicon layer 17 and the SiGe layer 12 therefore form a single liquid phase (a SiGe alloy). On cooling, the germanium atoms concentrate in the remaining liquid phase, which gradually decreases. The initial silicon layer 17 is thus transformed (locally) into a silicon-germanium alloy.

Again, the semiconductor layer 110B′ obtained after laser annealing in the second region 10B of the multilayer structure 10 comprises a germanium-depleted part and a germanium-enriched part. The germanium-enriched part forms the second semiconductor zone 100B. The first semiconductor zone 100A is, in this second embodiment, formed by the silicon layer 17 (now limited to the first region 10A).

FIGS. 3A to 3D illustrate a third embodiment of the manufacturing method, adapted to the formation of Fin Field-Effect Transistors (FinFETs) in the first and second regions 10A-10B of the multilayer structure.

In this third embodiment, the SiGe layer 12 of the multilayer structure 10 provided in step S1 is patterned in the form of a plurality of distinct fins 121 and the multilayer structure 10 further comprises electrical isolation trenches 16′ separating the fins 12 from each other. Furthermore, as in the first embodiment (FIGS. 1A-1D), the SiGe layer 12 has (before laser annealing) a germanium concentration of between 5% and 10%.

The fins designate elongate layer portions having a length (measured perpendicularly to the cross-sectional plane of the figures) much greater than their width (measured in the cross-sectional plane of the figures, parallel to the face of the substrate 11 on which the SiGe layer 12 is disposed).

Step S1 of providing the multilayer structure 10 in an embodiment comprises the following sub-steps of:
a) depositing the SiGe layer 12 onto the substrate 11, for example by epitaxy; b) etching the SiGe layer 12 so as to form the plurality of fins 121;
c) forming the electrical isolation trenches 16′ between the fins 121; and in an embodiment
d) depositing the protective layer 13 onto the SiGe layer 12.

Sub-step b) of etching the SiGe layer 12 is illustrated in FIG. 3A, while sub-step c) of forming the electrical isolation trenches 16′ and sub-step d) of depositing the protective layer 13 are illustrated in FIG. 3B.

Etching the SiGe layer 12 can be carried out through a resin mask or a hard mask (not represented in FIG. 3A), previously formed on the SiGe layer 12.

The SiGe layer 12 is etched to form two groups of fins 121, one located in the first region 10A of the multilayer structure 10 and the other located in the second region 10B of the multilayer structure 10. The distance d1 between two consecutive fins 121 in each group is in an embodiment less than the distance d2 separating the two fin groups. Thus, several FinFET transistors may be formed in each of the first and second regions 10A-10B.

In this third embodiment, it can be considered that the first and second regions 10A-10B are defined (or delimited) upon forming the multilayer structure 10. In other words, step S2 of defining the first and second regions 10A-10B is performed during the step S1 of forming the multilayer structure 10. The electrical isolation trench 16′ disposed between the two groups of fins corresponds to the electrical isolation trench 16 of FIGS. 1B and 2B.

In order to simplify formation of the multilayer structure 10, the protective layer 13 and the electrical isolation trenches 16′ may be formed by a same electrically insulating material, for example SiO₂. Beneficially, the electrically insulating material is deposited in such a way as to completely fill the trenches between the fins 121 and to form an extra thickness layer (i.e. the protective layer 13) on these same fins 121. Sub-step d) of depositing the protective layer 13 is then immediately consecutive to sub-step c) of forming the electrical isolation trenches 16′ and can be accomplished in the same deposition equipment.

Finally, step S1 of providing the multilayer structure 10 beneficially comprises a sub-step of depositing the laser reflection layer 14 onto the protective layer 13 (see FIG. 3B) or onto the fins 121.

After removal of the portion of the laser reflection layer 14 located in the second region 10B (see FIG. 3C; step S3), the multilayer structure is subjected to the laser annealing step S4 (see FIG. 3D) in order to obtain in the second region 10B a plurality of semiconductor layer portions 110B″ (in the form of fins) each having a germanium concentration gradient. Each semiconductor layer portion 110B″ results from the modification of at least one part of a fin 121.

In the case of fins, that is portions of very narrow width (typically between 5 nm and 50 nm), redistribution of the germanium atoms takes place not only from the substrate 11 towards the protective layer 13 but also from inside towards outside of the fins 121. The germanium atoms are thus concentrated at the interface with the protective layer 13 and also at the interface with the electrical isolation trenches 16′. Each portion of semiconductor layer 110B″ thereby comprises a germanium-depleted part 111 disposed at the centre (such as a core) and a germanium-enriched part 112 which wraps the germanium-depleted part 111 (such as a shell).

Each germanium-enriched part 112 in the second region 10B forms a second semiconductor zone 100B optimised for hole conduction and each unmodified fin 121 (of low concentration SiGe) in the first region 10A forms a first semiconductor zone 100A optimised for electron conduction.

In an embodiment, the laser annealing conditions are such that the fins 121 are completely molten and then recrystallised (in the second region 10B). Thus, the germanium-enriched parts 112 extend to the substrate 11, in other words over the entire height of the fins. This configuration is particularly beneficial for the performance of pFET transistors, given that the gate of these transistors generally covers all three sides of the fin (the upper face and the two side faces in the cross-sectional plane of FIG. 3D).

FIGS. 4A to 4E illustrate a fourth embodiment of the manufacturing method. This fourth embodiment resembles the third embodiment in that the multilayer structure 10 also comprises fins 122 distributed between the first and second regions 10A-10B and electrical isolation trenches 16′ between the fins 122. It is therefore also adapted to the formation of FinFET transistors.

Like FIGS. 3A-3B, FIG. 4A and FIG. 4B represent sub-steps of step S1 of providing the multilayer structure 10.

After depositing the SiGe layer 12 onto the substrate 11 (sub-step a)), the SiGe layer 12 and a portion of the substrate 11 are etched so as to form the plurality of fins 122 (see FIG. 4A; sub-step b)). In an embodiment, the portion of the substrate 11 which is etched at the same time as the SiGe layer 12 is made of silicon. This may especially be the thin silicon layer (also referred to as the active layer) of an SOI substrate, typically a layer of single crystal silicon. The thickness of the thin silicon layer is generally between 5 nm and 80 nm.

Then, with reference to FIG. 4B, the electrical isolation trenches 16′ and the protective layer 13 are formed as described in connection with FIG. 3B (sub-steps c) and d)) and, in an embodiment, using the same electrically insulating material.

During the laser annealing step S4 (see FIG. 4D), the germanium atoms contained in the SiGe layer 12 of each fin 122 are dispersed and then concentrated at the interfaces with the protective layer 13 and the electrical isolation trenches 16′, as described previously in connection with FIG. 3D. The result is the different fin-shaped semiconductor layer portions 110B″. In the case of an SOI substrate, laser annealing is beneficially performed so as not to melt the single crystal silicon layer of the SOI substrate through its entire thickness, in other words down to the buried oxide layer (BOX). This allows the fin-shaped semiconductor layer portions 110B″ to recrystallise into a single-crystal form.

In this fourth embodiment, the SiGe layer 12 beneficially has (before laser annealing) a germanium concentration greater than or equal to 30%. Such a concentration is important so that sufficient germanium atoms can be dispersed during the melting phase and then redistributed during the recrystallisation phase. The thickness of the SiGe layer 12 can then be smaller than in the other embodiments, for example between 5 nm and 10 nm (instead of 5 nm-100 nm).

Finally, in a step S5 illustrated by FIG. 4E, the protective layer 13 is removed in the first region 10A of the multilayer structure 10 (as is the laser reflection layer 14, if necessary), and then the SiGe layer 12 is then etched therein selectively with respect to the substrate 11. The electrical isolation trenches 16′ located in the first region 10A may also be etched (especially when they are formed by the same material as the protective layer 13).

At the end of this step S5, silicon fins 122 are obtained in the first region 10A of the multilayer structure 10 and SiGe-based fins 110B″ are obtained in the second region 10B (covered with the protective layer 13). Each fin 122 in the first region 10A forms a first semiconductor zone 100A and the germanium-enriched part 112 of each SiGe-based fin 110B″ (or semiconductor layer portion) forms a second semiconductor zone 100B.

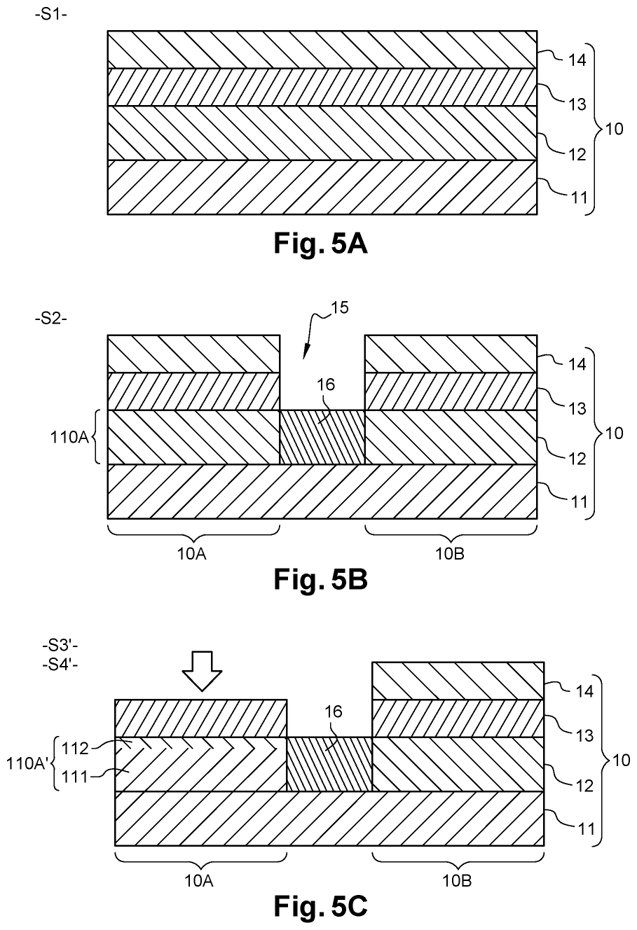

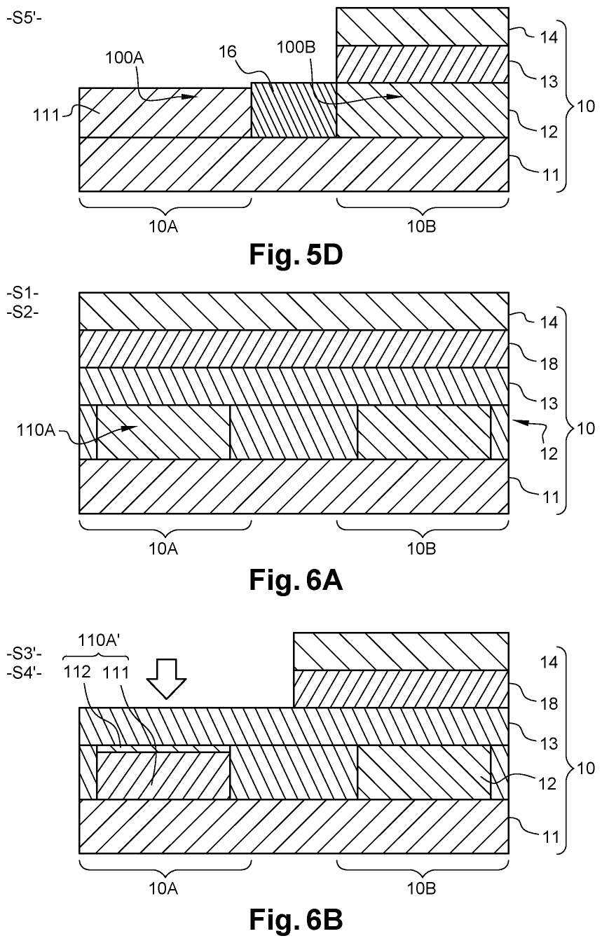

FIGS. 5A-5D, 6A-6D and 7A-7C represent three further embodiments of the manufacturing method.

In a manner common to these three other embodiments, the manufacturing method comprises the following steps S1, S2, S4′ and S5′:
S1: providing a multilayer structure 10 comprising a substrate 11 and a SiGe layer 12 disposed on the substrate 11 (cf. FIGS. 5A, 6A and 7A);
S2: defining in the multilayer structure 10 a first region 10A for containing the first semiconductor zone 100A and a second region 10B for containing the second semiconductor zone 100B (see FIGS. 5B, 6A and 7A); and
S4′: subjecting the multilayer structure 10 to laser annealing so as to modify one or more portions 110A of the multilayer structure 10 located in the first region 10A, each portion 110A comprising before the laser annealing part of the SiGe layer 12, each portion being modified so that it comprises after the laser annealing a germanium-depleted part 111 and a germanium-enriched part 112 disposed on the first part 111 (see FIGS. 5C, 6B and 7B); and
S5′: etching the germanium-enriched part 112 so as to expose the germanium-depleted part 111 (see FIGS. 5D, 6C and 7C).

As previously, the multilayer structure 10 beneficially comprises a protective layer 13 disposed on the SiGe layer 12. Each portion 110A then extends up to the protective layer 13. The protective layer 13 is removed in the first region 10A of the multilayer structure 10 before etching the germanium-enriched part 112 (step S5′).

Step S1 of providing the multilayer structure and step S2 of defining the first and second regions 10A-10B have been described previously.

The laser annealing step S4′ differs from the previously described step S4 in that the portion(s) of the multilayer structure 10 modified by the laser annealing is located in the first region 10A instead of the second region 10B. After removal of the germanium-enriched part 112, the germanium-depleted part 111 forms the first semiconductor zone 100A (optimised for electron conduction).

Thus, the final objective of the method according to these three embodiments is not to concentrate germanium atoms in the second region 10B to form the second semiconductor zone 100B (optimised for hole conduction), but on the contrary to deplete the SiGe layer 12 in the first region 10A to form the first semiconductor zone 100A.

Again, a laser reflection layer 14 may be used to locate the laser annealing. However, the laser reflection layer 14 is here formed only in the second region 10B of the multilayer structure.

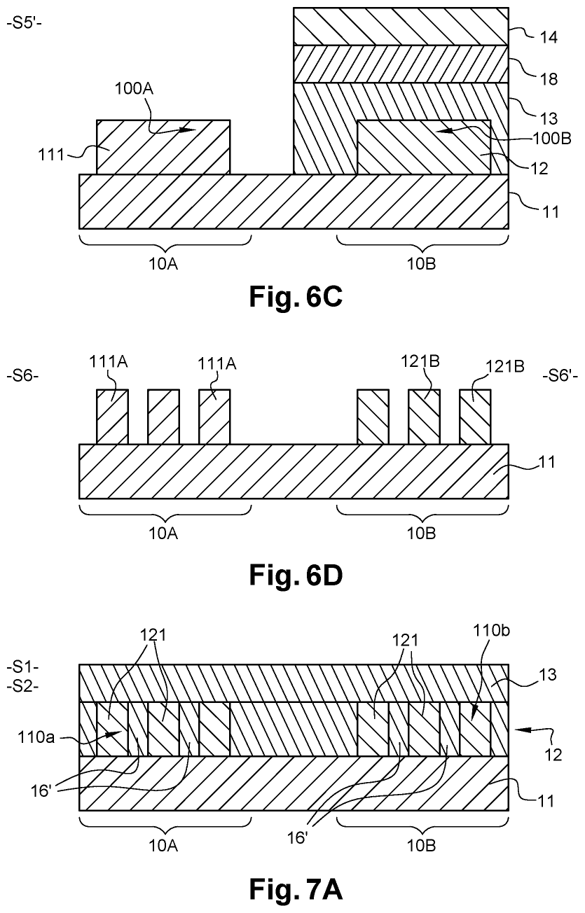

Thus, in the embodiments of FIGS. 5A-5D and 6A-6D, the multilayer structure 10 provided in step S1 further comprises the laser reflection layer 14 disposed on the protective layer 13 (or on the SiGe layer 12) and the manufacturing method further comprises, prior to the laser annealing step S4′, a step S3′ of removing a portion of the laser reflection layer 14 located in the first region 10A of the multilayer structure 10 (cf. FIGS. 5C and 6B).

FIGS. 5A to 5D illustrate a fifth embodiment of the manufacturing method.

Step S1 of providing the multilayer structure 10 and step S2 of defining the first and second regions 10A-10B (cf. FIG. 5A and FIG. 5B) are substantially identical to those described in connection with FIGS. 1A-1B (first embodiment). The only difference is that the SiGe layer 12 here has a germanium concentration greater than or equal to 30%.

After removing the portion of the laser reflection layer 14 located in the first region 10A (step S3′), the multilayer structure 10 is subjected to the laser annealing step S4′ in order to obtain, in the first region 10A, the (SiGe-based) semiconductor layer 110A′ comprising the germanium-depleted part 111 and the germanium-enriched part 112 (see FIG. 5C).

Then, in step S5′ represented by FIG. 5D, the protective layer 13 is removed in the first region 10, by selective etching with respect to the semiconductor layer 110A′, and then the germanium-enriched part 112 of the semiconductor layer 110A′ is entirely etched, so as to expose the germanium-depleted part 111. The germanium-depleted part 111 can also be etched in part (upper part), depending on the desired germanium concentration in the first region 10A. Indeed, the concentration of germanium in the semiconductor layer 110A′ decreases with a decreasing distance to the substrate 11.

The germanium-enriched part of the semiconductor layer 110B′ can be etched using an etching solution, for example a mixture of acetic acid, hydrofluoric acid and hydrogen peroxide.

The germanium-depleted part 111 forms the first semiconductor zone 100A, while the unmodified portion of the SiGe layer 12 forms the second semiconductor zone 100B.

FIGS. 6A to 6C illustrate a sixth embodiment of the manufacturing method.

This sixth embodiment differs from the fifth embodiment essentially in the way in which the first and second regions 10A-10B of the multilayer structure 10 are defined (step S2).

Here, the SiGe layer 12 is etched after it has been deposited onto the substrate 11 and before the protective layer 13 has been deposited, whereas in the fifth embodiment it is etched after the multilayer structure 10 has been completely formed (trench 15). In other words, steps S1 and S2 are performed as in the third embodiment (see FIGS. 3A-3B), except that the SiGe layer 12 is not patterned in the form of fins.

Thus, step S1 of providing the multilayer structure (FIG. 6A) comprises the following sub-steps of:
a) depositing the SiGe layer 12 onto the substrate 11, for example by epitaxy;
b) etching the SiGe layer 12 so as to obtain a first portion located in the first region 10A and a second portion located in the second region 10B;
c) forming an electrical isolation trench 16′ between the first and second portions of the SiGe layer 12; and in an embodiment
d) depositing the protective layer 13 onto the SiGe layer 12.

The protective layer 13 may be formed on the SiGe layer 12 by depositing the same electrically insulating material as that forming the electrical isolation trench 16′, as described in connection with FIG. 3B.

Step S1 of providing the multilayer structure 10 beneficially comprises a sub-step of depositing the laser reflection layer 14 onto the protective layer 13 (or onto the first and second portions of the SiGe layer 12).

Between sub-step d) of depositing the protective layer 13 and sub-step of depositing the laser reflection layer 14, step S1 of providing the multilayer structure 10 may also comprise a sub-step of forming a hard mask layer 18 on the protective layer 13. The hard mask layer 18 is made of SiN or SiO₂, for example. This hard mask layer 18 may also form part of the laser reflection layer 14 (SiO₂+SiN).

The hard mask layer 18 is etched into the first region 10A of the multilayer structure 10 after etching of the laser reflection layer 14 (step S3′) and, in an embodiment, before the laser annealing step S4′, as is represented by FIG. 6B.

As previously described in connection with FIG. 5C, laser annealing makes it possible to obtain in the first region 10A of the multilayer structure 10 a semiconductor layer 110A′ comprising a germanium-depleted part 111 and a germanium-enriched part 112 (cf. FIG. 6B).

FIG. 6C illustrates step S5′ comprising etching the protective layer 13 in the first region 10A and etching the germanium-enriched part 112. Both of these etching operations can be accomplished by employing the laser reflection layer 14 or the hard mask layer 18 (when the laser reflection layer 14 has been previously removed) as an etch mask.

After the step S5′ of etching the germanium-enriched part 112 illustrated in FIG. 5D or FIG. 6C, the manufacturing method may comprise the following steps of:
S6: etching the germanium-depleted part 111 so as to form a plurality of first fins 111A in the first region 10A of the multilayer structure 10;
S6′: removing the laser reflection layer 14 and the protective layer 13 located in the second region 10B, and then etching the unmodified portion of the SiGe layer 12 so as to form a plurality of second fins 121B in the second region 10B of the multilayer structure 10.

Thus, FinFET (NMOS and PMOS) transistor channel regions are formed in each of the first and second regions 10A-10B.

Etching (or patterning) of the germanium-depleted part 111 (step S6) can be accomplished immediately after step S5′ of etching of the germanium-enriched part 112. The first fins 111A are then covered with a mask, then the laser reflection layer 14, the hard mask layer 18 (if necessary) and the protective layer 13 are successively removed (by etching through the mask), to give access to the SiGe layer 12. Finally, the SiGe layer 12 is patterned to form the second fins 121B (step S6′).

The etching steps to form the first fins 111A in the first region 10A and the second fins 121B in the second region 10B may also be performed simultaneously (after removal of the laser reflection layer 14, the hard mask layer 18 and the protective layer 13).

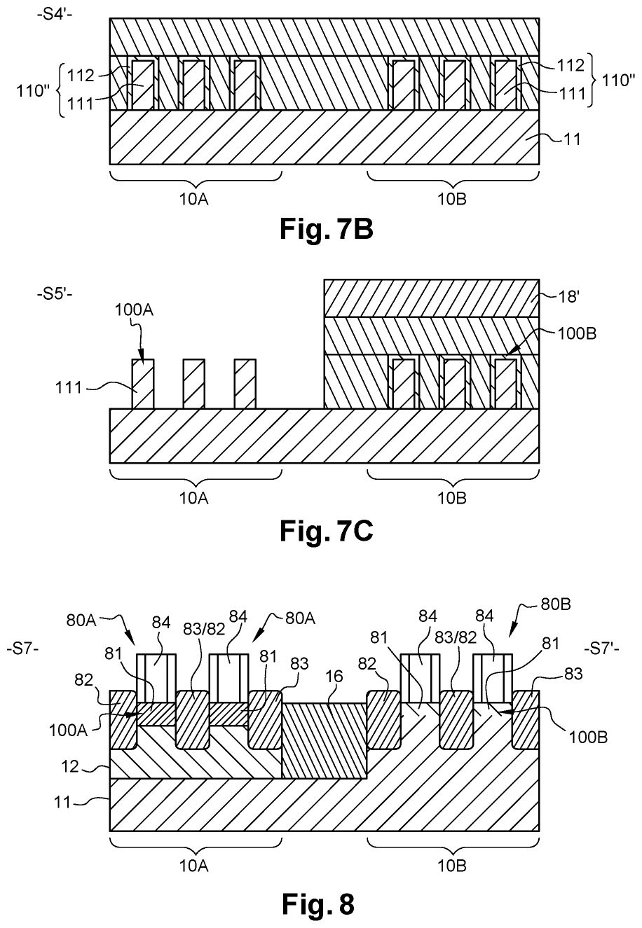

FIGS. 7A to 7C illustrate a seventh embodiment of the manufacturing method, adapted to the formation of FinFET transistors.

Step S1 of providing the multilayer structure 10 and step S2 of defining the first and second regions 10A-10B represented by FIG. 7A are carried out in a manner substantially identical to that described in connection with FIGS. 3A-3B (third embodiment). The SiGe layer 12 is especially patterned into a plurality of fins 121 distributed between the first and second regions 10A-10B and separated from each other by electrical isolation trenches 16′. A difference is that the SiGe layer 12 here has a germanium concentration greater than or equal to 15%.

Then, in step S4′ (see FIG. 7B), the multilayer structure 10 is subjected to laser annealing so as to modify portions 110A of the multilayer structure 10 located in the first region 10A and portions 110B of the multilayer structure 10 located in the second region 10B, each portion 110A, 110B comprising at least one part of a fin 121 and extending up to the protective layer 13.

To this end, the multilayer structure 10 is devoid of a laser reflection layer 14. The manufacturing method therefore does not include a sub-step of depositing the laser reflection layer 14 onto the protective layer 13, or a step of removing S3′ a portion of the laser reflection layer 14 located in the first region 10A. However, the multilayer structure 10 may comprise a hard mask layer (not represented) disposed on the protective layer 13.

Laser annealing thus affects all the fins 121 of the SiGe layer 12. Each fin 121 is transformed (at least in part) into a portion of semiconductor layer 110″ comprising a germanium-depleted part 111 and a germanium-enriched part 112 which wraps the germanium-depleted part 111.

In step S5′ of FIG. 7C, the protective layer 13 and the germanium-enriched part 112 of the semiconductor layer portions 110″ are successively etched in the first region 10A. These two etching operations are performed after forming a hard mask 18′ in the second region 10B, on the protective layer 13. The hard mask 18′ is obtained by etching a portion of a hard mask layer deposited onto the protective layer 13 before laser annealing, for example during formation of the multilayer structure (step S1), or after laser annealing (step S4).

Each germanium-depleted part 111 located in the first region 10A forms a first semiconductor zone 100A optimised for electron conduction and each germanium-enriched part 112 located in the second region 10B forms a second semiconductor zone 100A optimised for hole conduction.

In an alternative embodiment of the method according to FIGS. 7A-7C, adapted to the formation of planar transistors (e.g. single gate MOSFET), the SiGe layer 12 of the multilayer structure 10 is left intact (i.e. it is not patterned) before the laser annealing step S4′. Then, at least one part of the SiGe layer 12 extending into the first region 10A and into the second region 10B is subjected to laser radiation. The protective layer 13 and the germanium-enriched part 112 obtained after laser annealing are etched only in the first region 10A.

The laser annealing conditions (step S4 or S4′) may differ between the different embodiments, depending on the initial composition of the multilayer structure 10. They can be determined beforehand by means of simulations, experiments or measurements.

FIG. 8 schematically represents optional steps S7 and S7′ of the manufacturing method, compatible with any of the embodiments previously described.

These steps S7 and S7′, carried out after laser annealing step S4, step S5 of removing the SiGe layer 12 or step S5 of removing the germanium-enriched part 112 (according to the embodiment), respectively comprise forming one or more nFET transistors 80A in the first region 10A of the multilayer structure 10 and forming one or more pFET transistors 80B in the second region 10B of the multilayer structure 10. The way in which these steps are carried out especially depends on the type of field effect transistor desired: single gate MOSFET transistor, multiple gate MOSFET transistor (e.g. FinFET), etc.

Each transistor 80A, 80B comprises a channel region 81 disposed on the substrate 11, a drain region 82 and a source region 83 disposed on the substrate 11 on either side of the channel region 81 and a gate structure 84 disposed on the channel region 81. The channel region 81 of the nFET transistors is formed in a first semiconductor zone 100A optimised for electron conduction, while the channel region 81 of the pFET transistors is formed in a second semiconductor zone 100B optimised for hole conduction.

In the case of single gate MOSFETs, the channel regions 81 of transistors of the same type (nFET or pFET) may all be formed in the same semiconductor zone (first semiconductor zone 100A or second semiconductor zone 100B). In the case of FinFET transistors, each fin (111A, 121, 121B, 122) or fin-shaped semiconductor layer portion (110″, 110B″) comprises the channel region of a single transistor.

The order in which steps S7 and S7′ are performed beneficially varies according to the embodiment of the manufacturing method.

For example, in the first three embodiments (FIGS. 1D, 2D and 3D), it is beneficial to begin with forming the pFET transistors in the second region 10B, while the first semiconductor zone 100A is still covered with the protective layer 13 and the laser reflection layer 14. The laser reflection layer 14 in the first region 10A can serve as an etch mask to remove the protective layer 13 (and electrical isolation trenches 16′, if necessary) in the second region 10B. The nFET transistors can then be formed after masking the pFET transistors and removing the laser reflection layer 14 and the protective layer 13 in the first region 10A.

In the next four further embodiments (FIGS. 4E, 5D, 6C and 7C), it is beneficial to begin with forming the nFET transistors in the first region 10A, while the second semiconductor zone 100B is still covered with the protective layer 13 (the hard mask layer 18 and/or the laser reflection layer 14, if necessary). The pFET transistors can then be formed after the nFET transistors have been covered with a mask and the protective layer 13 (the hard mask layer 18 and/or the laser reflection layer 14, if necessary) has been removed in the second region 10B.

Forming the FinFET transistors in the fifth and sixth embodiments will then begin with patterning the first semiconductor zone 100A (of depleted SiGe) to form the fins (step S6; FIG. 6D).

Steps S7 and S7′ of forming the nFET and pFET transistors can also be performed simultaneously.

As previously indicated, the different lattice parameters between silicon and silicon-germanium have the effect of generating compressive stress in each second semiconductor zone 100B. The channel regions 81 of the pFET transistors 80B are therefore compressively stressed. Since each second semiconductor region 100B further has a high concentration of germanium, the pFET transistors 80B can exhibit performance comparable to that of the nFET transistors 80A formed in the first region 10A.

In the embodiment of FIGS. 2A-2D, a technique may be implemented to tensile-stress the channel region 81 of the nFET transistors, thereby improving electron mobility and increasing performance of the nFET transistors. For example, the drain and source regions 82-83 may be formed by etching cavities into the first semiconductor zone 100A on either side of the gate structure 83, and then performing doped silicon epitaxy so as to fill the cavities.

In the case of FinFET transistors, laser annealing is beneficially performed so as not to alter (i.e. melt) the substrate 11. Indeed, the latter may contain dopants in order to form a ground plane or back gate in FinFET transistors.

It will be appreciated that the various embodiments and aspects of the inventions described previously are combinable according to any technically permissible combinations.

The articles “a” and “an” may be employed in connection with various elements, components, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

1. A method for manufacturing a semiconductor device comprising a first semiconductor zone optimised for electron conduction and a second semiconductor zone optimised for hole conduction, the method comprising:
providing a multilayer structure comprising:
a substrate, and
a silicon-germanium layer disposed on the substrate;
defining in the multilayer structure a first region for containing the first semiconductor zone and a second region for containing the second semiconductor zone, and
subjecting the multilayer structure to laser annealing so as to modify a portion of the multilayer structure located in the second region, said portion comprising prior to laser annealing a part of the silicon-germanium layer, said portion having, after laser annealing, a germanium concentration gradient with a germanium concentration which increases towards an upper face of said portion.

2. The method according to claim 1, wherein the multilayer structure further comprises a protective layer disposed on the silicon-germanium layer, wherein said portion extends up to the protective layer prior to laser annealing and wherein said portion has after laser annealing a germanium concentration which increases towards an interface with the protective layer.

3. The method according to claim 2, wherein the multilayer structure further comprises a laser reflection layer disposed on the protective layer and configured to decrease efficiency of laser annealing, the method further comprising, prior to laser annealing, removing a portion of the laser reflection layer located in the second region of the multilayer structure.

4. The method according to claim 3, further comprising, after laser annealing, removing the protective layer in the second region of the multilayer structure and removing the laser reflection layer and the protective layer in the first region of the multilayer structure.

5. The method according to claim 3, wherein the defining of the first and second regions of the multilayer structure is performed after the providing of the multilayer structure and comprises the following sub-steps of:
etching a trench in the multilayer structure, the trench extending through the laser reflection layer, the protective layer and the silicon-germanium layer to the substrate, and
filling the trench with an electrically insulating material over at least an entire thickness of the silicon-germanium layer.

6. The method according to claim 1, wherein:
the silicon-germanium layer has a germanium concentration greater than or equal to 10% prior to laser annealing;
the multilayer structure further comprises a silicon layer disposed on the silicon-germanium layer, and
said portion further comprises prior to laser annealing a part of the silicon layer.

7. The method according to claim 1, wherein the silicon-germanium layer has prior to laser annealing a germanium concentration of between 5% and 10%.

8. The method according to claim 1, wherein:
the silicon-germanium layer has a germanium concentration of between 5% and 10% prior to laser annealing;
the silicon-germanium layer comprises a plurality of fins distributed between the first and second regions of the multilayer structure; and
the multilayer structure further comprises electrical isolation trenches separating the fins from each other;
the multilayer structure is subjected to laser annealing so as to modify several portions of the multilayer structure located in the second region, each portion comprising at least one part of a fin prior to laser annealing.

9. The method according to claim 8, wherein the multilayer structure further comprises a protective layer disposed on the silicon-germanium layer, wherein said portion extends up to the protective layer prior to laser annealing and wherein said portion has after laser annealing a germanium concentration which increases towards an interface with the protective layer, and wherein the providing of the multilayer structure comprises the following substeps of:
a. depositing the silicon-germanium layer onto the substrate;
b. etching the silicon-germanium layer so as to form the plurality of fins;
c. forming the electrical isolation trenches between the fins, and
d. depositing the protective layer onto the silicon-germanium layer.

10. The method according to claim 9, wherein the protective layer and the electrical isolation trenches are formed by a same electrically insulating material.

11. The method according to claim 1, wherein:
the silicon-germanium layer has, before laser annealing, a germanium concentration greater than or equal to 30%;
the silicon-germanium layer and a portion of the substrate are patterned in the form of a plurality of fins; and
the multilayer structure is subjected to laser annealing so as to modify several portions of the multilayer structure located in the second region, each portion comprising prior to laser annealing at least one part of a fin;
the method further comprises, after laser annealing, etching the silicon-germanium layer in the first region of the multilayer structure, etching the silicon-germanium layer being selective with respect to the substrate.

12. The method according to claim 11, wherein the multilayer structure further comprises a protective layer disposed on the silicon-germanium layer, wherein said portion extends up to the protective layer prior to laser annealing and wherein said portion has after laser annealing a germanium concentration which increases towards an interface with the protective layer and wherein the providing of the multilayer structure comprises the following substeps of:
a. depositing the silicon-germanium layer onto the substrate;
b. etching the silicon-germanium layer and the portion of the substrate so as to form the plurality of fins;
c. forming the electrical isolation trenches between the fins, and
d. depositing the protective layer onto the first silicon-germanium layer.

13. The method according to claim 12, wherein the protective layer and the electrical isolation trenches are formed by a same electrically insulating material.

14. The method according to claim 1, wherein laser annealing is performed by exposing the multilayer structure to laser radiation having a wavelength of between 200 nm and 600 nm and an energy density of between 0.1 J/cm² and 10 J/cm² for a duration of between 10 ns and 1000 ns.

15. The method according to claim 1, further comprising forming an N-channel field effect transistor, referred to as an nFET transistor, in the first region of the multilayer structure and forming a P-channel field effect transistor, referred to as a pFET transistor, in the second region of the multilayer structure.
